(19) United States
(12) Patent Application Publication
(10) Pub. No.: US 2008/0225476 A1
(43) Pub. Date: Sep. 18, 2008

(54) TAB WRAP FOLDABLE ELECTRONIC ASSEMBLY MODULE AND METHOD OF MANUFACTURE

(76) Inventor: Chris Karabatsos, Kingtston, NY (US)

Correspondence Address: WHITE & FUDALA, 57 BEDFORD STREET, SUITE 103, LEXINGTON, MA, 02420, US

(21) Appl. No.: 11/306,803

(22) Filed: Jan. 11, 2006

(51) Int. Cl. H05K 5/00; H01R 43/00

(52) U.S. Cl. 361/684; 29/854

(57) ABSTRACT

A high-density memory module is made up of two memory boards, each with memory elements affixed to each of two sides, the two memory boards disposed on either side of a central rigid substrate, each memory board having a flexible wiring array, electrically and mechanically affixed at one end to one of the memory board and at the other end to the other of the memory boards, the flexible wiring array wrapped at its midpoint around a bottom of the central rigid substrate, so that two linear arrays of comb tabs affixed to the flexible wiring array are disposed in proximity to the bottom of the central rigid substrate, so that the central rigid substrate may be inserted into a mating electrical connector, making an electrical connection with both memory boards.

### FIELD OF THE INVENTION

This invention relates to electronic circuit packaging, and more specifically to the packaging of integrated circuit chips, in the form of electronic modules made up of multiplicities of parallel-positioned printed circuit boards which communicate with each other through flexible interconnecting material.

### DESCRIPTION RELATIVE TO THE PRIOR ART

Designers of electronic circuits are forever striving to reduce the size of electronic assemblies through miniaturization of the electronic components to achieve high density and high frequency operation. Space utilization is enhanced by using modules of low physical profile and of high density of electronic components.

Modules containing high-speed memory chips, such as SDRAMS, RDRAMS, FLASH, and SRAMS, Logic Chips, or any combination thereof, are typically interconnected by mounting to connectors on a motherboard.

These modules require both the grouping of arrays of integrated circuit chips in close proximity, and the electrical interconnection of those chips with each other through short, high-speed paths. Furthermore, the mating connectors on the motherboard must support the modules mechanically, as well as providing electrical connectivity. The modules must have combs of pads to mate with contacts in connector cavities.

The system's packaging configuration must typically be flexible enough to allow expansion of the memory capacity by addition or substitution of memory modules in a motherboard arrangement. However, space considerations often dictate a limitation in the amount of expansion possible. Furthermore, cooling also becomes a problem when the density of electronic components becomes very high.

Another factor which must be considered is that fewer connectors are allowed in a memory subsystem as the operating frequency of the interface between the controller and the memory modules on the motherboard increases due to physical RLC parasitic properties Inherent in such a packaging configuration.

There is a need for an improved packaging technique that would provide for the convenient expansion of the memory capacity in a system without requiring a large space allocation for additional memory modules. Such a system would have to fit into the pre-existing physical configuration, making allowances for supporting structures, such as connectors, already existing on the motherboard.

The high density of memory chips on memory modules and the requirement for high-speed connectivity are characteristics that cannot be compromised in such an improved configuration. Thus, the proposed packaging technique solution must be one that does not require substantial space allocation for future expansion, one that provides a configuration that can be easily cooled with essentially the same techniques already used in these systems, and one that does not degrade the performance of the memory chips and of the system.

This objective is achieved by combining a number of printed circuit boards of substantially the same characteristics, bonded to a common flexible interconnecting substrate that is part of the signal layers arrangement of the boards. The flexible interconnecting layer accommodates conducting tabs in comb cluster configurations and provides interconnections between tabs and boards on both sides. The tabs of the combs are formed with the same etching printed wire process as the circuit boards.

The prior art teaches that a multilayer printed circuit board for memory modules with multiplicity of memory chips attached to one or both sides of the board to be able to utilize similar comb tabs and connectors as in the present invention.

The present invention, in contrast, accommodates two or more such memory module boards utilizing the same pair of connector comb tabs. In accordance with this invention, printed wires are etched on the reverse side layer of the comb tabs bringing the connection of each tab from one board to the other as required.

The resulting assembly provides a solution offering a density of memory elements not previously available, which are inserted into the same circuit board edge connectors as previously used in the recent prior art.

### SUMMARY OF THE INVENTION

It is the general object of this invention to provide a high-density packaging configuration for use in computer memory systems. It is a further general object of this invention to alternatively provide such a packaging configuration without sacrificing speed of access of the memory.

It is a specific object of this invention to provide such high-speed configuration by means of a multi-circuit board array, wherein the interconnection between boards is made by arrays of printed conductors having high conductivity and low inter-conductor capacitance and inductance.

According to one aspect of the invention, an electronic assembly includes at least two multi-layer circuit boards of certain layer arrangement for signals and power, each of which has commonality of comb tabs, conductive leads and connecting stations applied thereto.

Each board has a first face and a second face, which are parallel to each other. All individual circuit board layers are located in close proximity to the other layers, and one or more layers affording a flexible section as integral part of the boards are provided, one of which contains a multiplicity of conductors and combs in strategic locations, each conductor having a first end and a second end and each comb tab has an end not connected to anything and with the other end connected to single or multiple points on each board.

The first end of each tab is free of connections. The second end is connected via wires to pads or via holes on the first face and second face of each board. Both boards are of similar dimensions. Means are provided for maintaining the boards in a configuration of close proximity to each other so that electronic signals that return ground and power paths may, also, travel from any board in the array to an adjacent board through the ground and power planes that are connected to ground and power tabs of each comb cluster.

According to a second aspect of this invention, the means for maintaining the finished boards in close proximity with the rigid substrate has a multiplicity of pins soldered to predetermined vias of each board. The vias where the pins are soldered are connected to internal power planes of the boards if so chosen.

According to a third aspect of this invention, the means for maintaining the boards in close proximity to the rigid substrate and in a rigid structure is a metal clip with pressure plates pressing against the memory chips or other electronic components and enclosing both boards with said components and pressing some of them against the rigid substrate.

According to a fourth aspect of this invention each board contains at least one pin via, with each pin via sized dimensioned to accommodate passage of at least one pin. The pin vias on adjacent boards are aligned to accommodate the pins, and each pin is affixed to adjacent boards by soldering. This is a method of maintaining the boards in close proximity but is not the only method that can be used.

According to yet another aspect of the invention, the assembly includes means for cooling the assembly, namely, maintaining spacing between adjacent boards such that cooling air may freely circulate between said adjacent boards.

According to still another aspect of the invention, the cooling can be accomplished by use of heat transferring substrate used as the rigid means for wrap around of the flexible portion with the tabs.

According to yet another aspect of the invention, a method for manufacturing the electronic module from a printed circuit multilayered substrate includes the steps of etching comb pads, circuit pads, circuit vias, pin vias, signal wiring, cutting one or more gaps into the flexible portion of the substrate, cutting a multiplicity of gaps separating the printed circuit substrate into board sections, forming notches at the ends of the circuit boards, creating an upper board, a lower board and snap-offs are formed on the sides of each board.

The method next includes mounting the electronic components onto the boards. Following these steps are the steps of soldering the electronic components to the boards, breaking the side snap-offs, so that the two boards are free of the frame to rotate around the rigid substrate with adhesive at the end of the wrap around section until they are in close proximity to each other, inserting post pins through the pin vias, and affixing the posts to the pin vias or attaching mechanical means. The method next includes pressing both sides of the flexible substrate with the adhesive on the reverse side onto the rigid plate for permanence and for formation of the right thickness around the tabs to form the edge connector suitable for insertion into a connector cavity.

According to another aspect of the invention, the attachment of the posts to the pin vias is by means of soldering.

According to another aspect of the invention, the attachment of the posts to the pin vias is done by mechanical means such as press fitting and or pressure retained or screw type.

According to another aspect of the invention, the final assembly is constructed by means of a clip engulfing the boards with the chips around the rigid substrate and exerting pressure against the boards and components from both sides onto the rigid substrate.

According to final aspect of the invention, the clip end tabs are allowed to engage into the upper end notches of the rigid substrate and of the boards to complete the module assembly.

### BRIEF DESCRIPTION OF THE DRAWINGS

These, and further features of the invention, may be better understood with reference to the accompanying specification and drawings depicting the preferred embodiment, in which:

FIG. 1 depicts a perspective view of the back face of a memory module board after the stage of board manufacture.

FIG. 2 depicts a perspective view of the front face of the memory module board of FIG. 1.

FIG. 2a depicts a cross sectional view of the memory module board of FIGS. 1 and 2 with comb tabs on the front face.

FIG. 2b depicts a cross sectional view of the memory module board of FIGS. 1 and 2 with comb tabs on the back face.

FIG. 2c depicts a cross-sectional view of a memory module board with the flex area midway between the top and bottom layers of the board.

FIG. 3 depicts a cross-sectional view of the memory module assembly.

FIG. 3a depicts a cross-sectional view of the memory module assembly with heat sink affixed.

FIG. 4 depicts an elevation view of the rigid substrate plate shown in FIG. 3 and FIG. 3a, with a section for wrap around.

FIG. 4a depicts a side elevation view of the component circuit boards shown in FIG. 3 and FIG. 3a.

FIG. 5 depicts a perspective view of a retaining clip assembly.

FIG. 6 depicts a layer with single or double copper face not yet imaged, and showing a FLEX area where the COMB tabs will be imaged.

FIG. 6a depicts a layer with single or double copper face not yet imaged and showing a cross-hatched section to be removed before the final sandwich of all layers takes place.

FIG. 7a depicts a top plan view of a circuit board with two component areas separated by a central flexible area.

FIG. 7b depicts a side elevation view of the circuit board in unfolded configuration.

FIG. 7c depicts a side elevation view of the circuit board folded about a central substrate and retained in position by retaining pins.

### DESCRIPTION OF THE PREFERRED EMBODIMENTS OF THE INVENTION

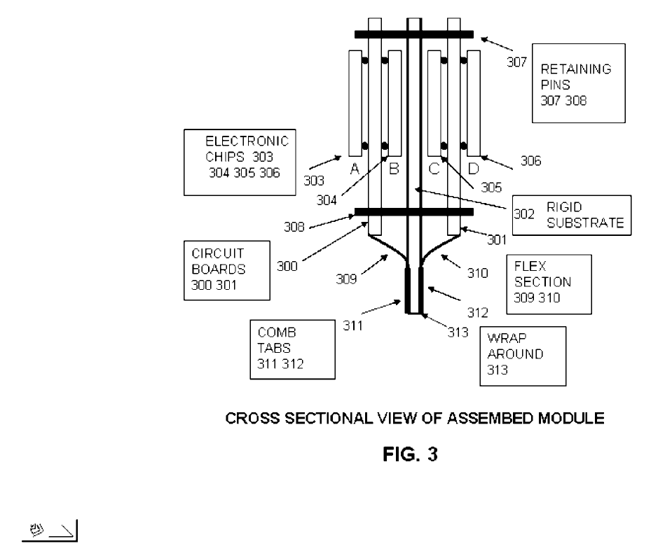

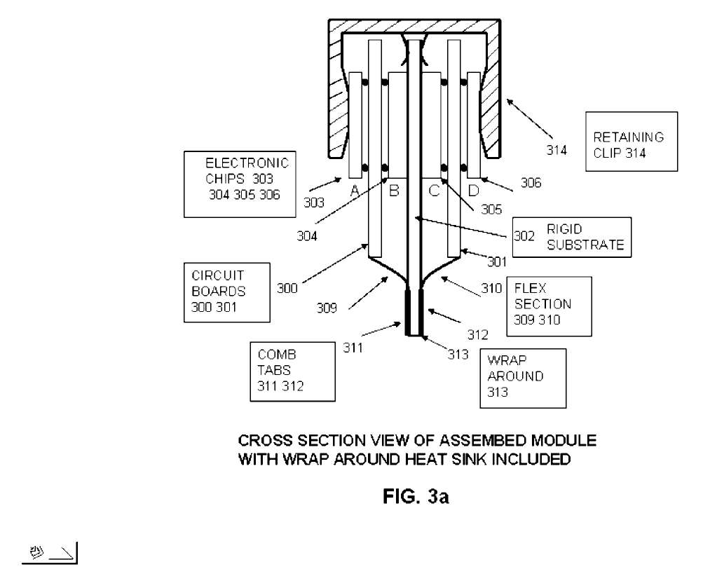

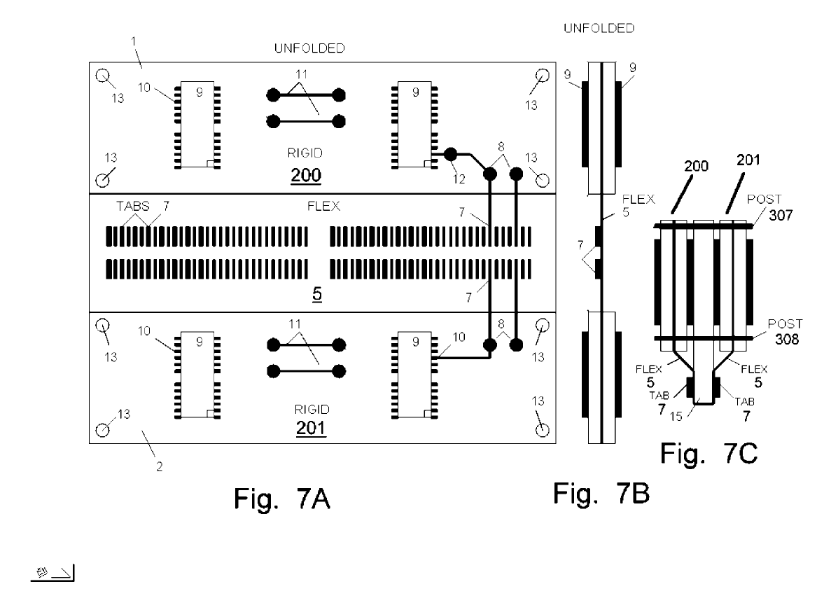

The current invention may be understood by referring to FIG. 7A, which shows a plan view of a memory board which has been fabricated with a flexible, printed wiring area in the center in area entitled “FLEX”, and two rigid areas 1,2 at the top and bottom of the flexible area, respectively. It is seen that this memory board contains memory chips 9, affixed to the board with it pins 10 soldered thereto. The central, flexible area contains tabs 7, which are electrically connected to elements of the board by leads terminating in pads 8. In this figure the pads 8 are further connected to a memory chip 9 by further connection through pad or via 12. The memory board further has holes 13 bored at positions which will allows restraining pins or posts 307, 308 to pass through, as seen in FIG. 7C and FIG. 3.

FIG. 7B is a right side elevation view of the memory board of FIG. 7A. The flexible area of FIG. 7A is fabricated as one of the layers of the memory board, together with the rigid material, as will be later described and explained. A central rigid substrate 15 is the substrate around which the flexible portion of the assembly, containing connecting wires and tabs, is wrapped. This central rigid substrate is the major structural support of the whole assembly, providing rigidity thereto.

Referring next to FIG. 7C, the bottom area 2 has been rotated to the right until it is parallel to the upper area 1, with the flexible material 5 forming a loop at the bottom and between the two areas. A central rigid substrate 15 has been inserted between the upper 1 and lower 2 areas of the board, with the two tab arrays 7 disposed on either side of the central rigid substrate 15.

The entire structure is now secured by means of posts 307 inserted in the holes 13 of the memory board at the top and bottom corners of the boards.

There are two such parallel comb arrays spaced from each other so that when the flexible layer is wrapped around and glued to a rigid substrate, a cluster of tabs appears on each side of the rigid substrate to form an edge connector. The thickness of the rigid material must be such in the area where the tabs appear so that the overall thickness of the rigid material and the flexible material with the comb tabs constitute the thickness required for mating with the pins inside the connector cavity. These tabs become the connecting points to the two parallel rows of pins in the cavity of the connector in which the final assembly is inserted.

The other section of the rigid substrate can be of different width and shape to accommodate application requirements.

The connecting wires can be accommodated on the same layer as the layer of the comb tabs provided that space is available between comb tabs to run wires through. The back side layer of the comb tabs can also accommodate cross-board connections. The tabs are connected to printed wires and these wires propagate through the different layers through copper plated holes and are channeled to appropriate memory chip pins or connecting points in the same manner as any other signal connection in conventional prior art printed circuit boards.

The rigid material with the combs wrapped around it, provides a solid edge connector structure for interconnection of the components on the module with a motherboard.

The connection is typically made by means of a female connector physically affixed to, and electrically connected with, the motherboard. This connector performs the functions of both electrically connecting the module with the motherboard, and physically supporting the module.

This structure is compared to the prior art, in which each module was made up of a single multilayered substrate, with chips on one or both sides, and a female connector for each such module located on the motherboard. In the present invention, however, the module is made up of two or more board substrates, each mounted substantially close to the other substrates on the same module, and each cluster of board substrates affixed to the center rigid substrate, forming a single rigid structure with common comb tabs whose final use is the insertion into a connector cavity.

The method of affixing the board substrates and the rigid material together is typically done by metal pins, which pass through the board substrates at strategic locations and are attached by soldering or mechanical fastening.

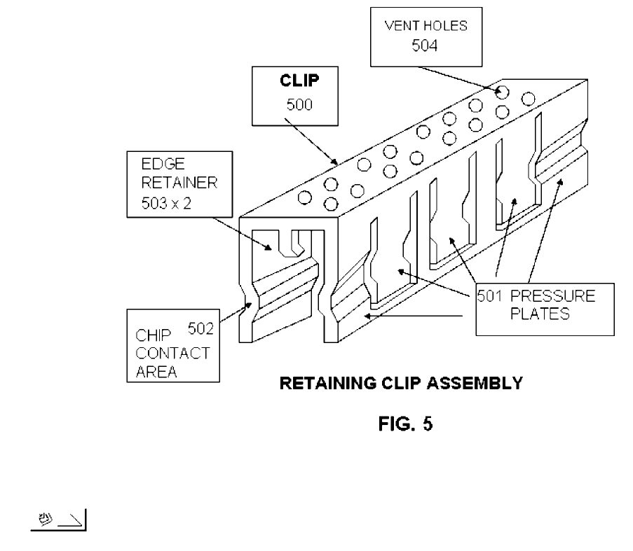

Pins are not the only way to affix the boards to the substrate. A letter “U”-shaped metal clip with spring plates and retaining tabs at the end can be used to bring the circuit boards against the rigid substrate. Such clip can take different forms and shapes as the application requires. A typical clip appears in FIG. 5, and is further shown in the side elevation view of the entire board assembly, with clip attached, in FIG. 3A.

Another method of attachment is to have the components that are attached to the circuit boards facing the rigid substrate permanently or semi-permanently affixed to it by means of adhesives or other substances with affixing properties.

In the case where pins are used to affix the boards to the rigid plate, spacing between adjacent boards and the rigid material is maintained such that a passageway between the boards is maintained sufficient to allow cooling air to circulate if the pin type is used. In the case where a clip or clips are used to affix the boards to the rigid plate, the two adjacent boards are pressed against the rigid substrate and the memory chips are allowed to press against the rigid plate surfaces. The rigid material and the body of the memory chips become one unit with heat spreading properties. This clip-type arrangement lends itself to easy manufacturing of the modules with favorable thermal properties.

The rigid material in the form of a thin plate or with multi-shaped portions, like a printed circuit board with copper un-etched surfaces in selected areas where board components are facing it and with the area behind the comb tabs etched, can be of substantially the same material as the printed circuit boards. Other materials of metallic nature or any other type that can maintain overall rigidity of the final assembly can also be used.

The boards that constitute a module are multilayered boards originally manufactured as a single board assembly with the flexible section as part of the layers of the final board. The side edges of the boards are connected by narrow snap-offs to board side sections that will be discarded upon completion of the assembly.

More specifically, the manufacture of this configuration begins with a single, flat piece of multilayer printed circuit substrate, with channels or gaps cut to facilitate later separation into two separate boards connected only with the flexible portion between them.

Individual sections of the board that become part of the final module assembly have all but two layers separated from each other by a cut out portion of length appropriate to facilitate the wrap around the rigid substrate.

The other two layers are contiguous and they extend from the end of one board to the other end of the other board without interruption or gap.

The flexible section can contain holes placed in strategic locations so that when the edge connector is formed by the wrap-around it permits insertion into female connectors with separated cavities. The flexible layers can be of the same material as the other board layers, such as FR-4, or can be of the flexible type such as KAPTON or ACRYLIC.

In the construction of the printed circuit boards, it is required that certain characteristic impedance is achieved for signal lines. For example, for 60 OHM impedance of signal lines, the spacing between the top layer and the next power or ground layer is less than 0.004 inches and the copper section approximately 0.001 inches each. One can see that the wrap-around of that thickness of material is easily achieved.

Once the boards are pinned or attached to the center substrate, there is no further flexing. This type of construction is less expensive than the utilization of other materials such as KAPTON.

The combs of tabs are etched on one face of these flexible layers. The interconnections between the comb tabs and the boards are also etched in normal board construction process. For certain tab widths, the interconnecting lines from tabs to opposite boards can be on the same side as the comb tabs.

The components are mounted on etched footprints on both sides of each single board flat surface. This allows the use of standard manufacturing techniques, such as pick and place surface mounting and solder re-flow. Once all the intended electronic components are soldered onto the two-board assemblies, the boards are liberated from the larger printed circuit board by snapping off the holding portions to the perimeter. Appropriate adhesive type is then spread on the reverse side of the combs to facilitate permanent adherence to the rigid substrate.

Next, a rigid material substrate or a metallic plate of proper thickness or FR-4 plate with copper surfaces is placed in a position so that the two sections each containing a comb of tabs is rotated around it. Finally, two sections are forcibly rotated into a position in close proximity to the rigid substrate and are pressed for permanency into the rigid substrate.

The components of each board on the side facing the substrate are either spaced some predetermined distance away or are allowed to touch the substrate in a permanent or semi-permanent state. After a desirable spacing between components of both boards is achieved, both boards and the substrate are arranged together to achieve the final module assembly and rigidity. If pins are used, they are soldered or fastened to each board and rigid plate. The pins can be connected to internal power planes for better power distribution. The length of the pins is determined to provide low inductance and low package profile.

If the clip method of board attachment is used, the memory chips will be allowed to touch the rigid substrate under some pressure exerted by the clip plates and/or be assisted by adhesive substance. The end clip tabs will be allowed to engage in the upper notches formed at the upper end of the boards and of the rigid plate on both end sides. This technique is particularly suitable for high-density applications such as memory modules.

The resulting assembly produced by the above technique thus provides for short wire lengths and low inter-conductor capacitance and inductance essential for use for memory systems utilizing a high speed DATA BUS in the high MHz and or Giga-Hz frequency range.

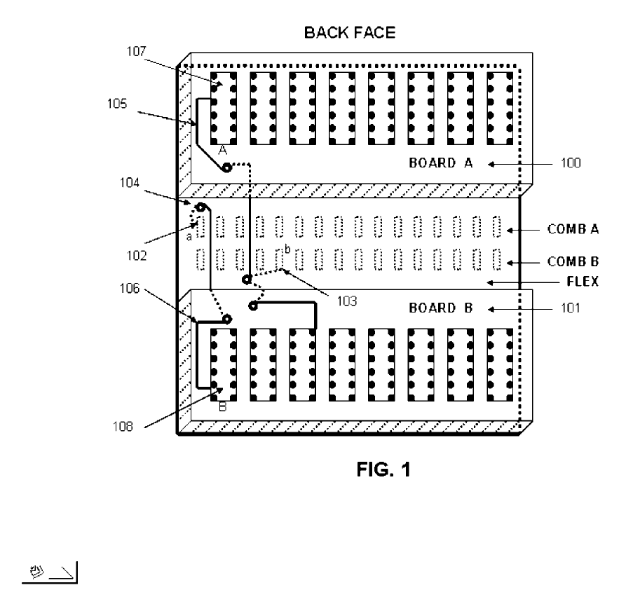

Further details of the invention may be understood by next referring to FIG. 1, a sample back face view of a memory module board is depicted as it appears after the stage of board manufacturing. The entire base structure as seen in FIG. 1 was formed in steps in the normal processes known in prior art for board manufacturing. BOARD A 100 and BOARD B 101 have substantially the same properties, and correspond to the upper an lower areas 1,2 of FIG. 7A. Sample component footprints 107 and 108 of one face of the boards, sample printed wires 105 and 106, sample connecting wires, visible and buried, to tabs 102 and 103 and via 104 are shown for reference. In practice, of course, a multiplicity of these elements appear on each section of the board. COMB A and COMB B tabs on front face of the boards shown in dotted lines are part of the flex layer. The boards are multilayered boards to accommodate the dense inter-component wiring, and the flex area makes up one of these layers.

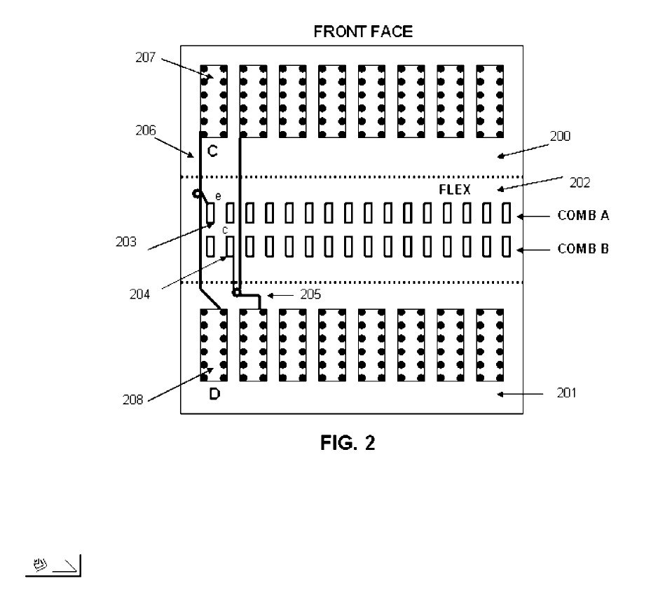

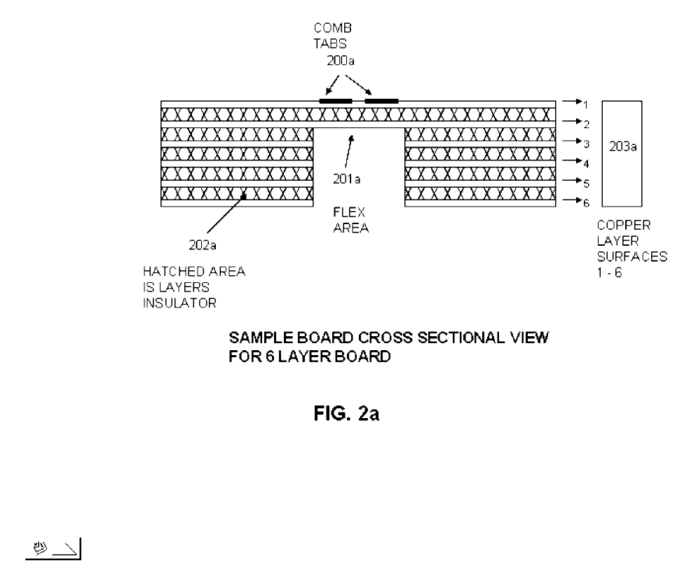

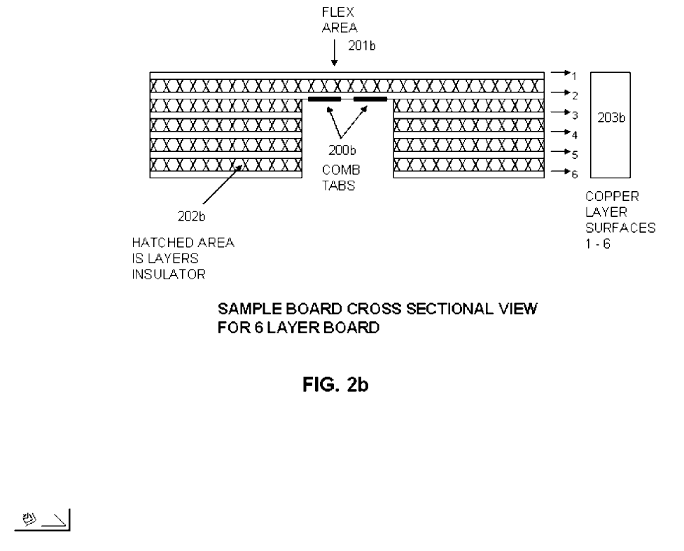

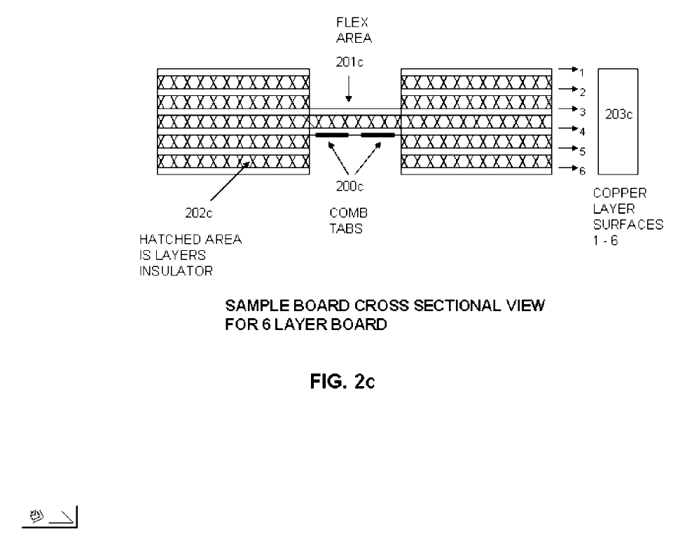

Referring next to FIG. 2, board sections 200 and 201 are shown with the representative component footprints 207 and 208. In practice a multiplicity of such components will be included. COMB A and COMB B with visible tabs 203 and 204 on flex section 202 and visible connecting wires 206 and 205 are also shown. The entire face of the FRONT FACE side of the boards is constructed with the layers extending to the entire face and said layers afford a flexible section 202 where the comb tabs are formed. Although the flexible section is shown as part of the FRONT FACE in this figure, The flexible layers can be embedded between layers in various configurations as shown in FIGS. 2A, 2B, and 2C. Referring next to FIG. 2a, a cross sectional view of a sample board with one possible flex layer configuration is shown. This embodiment is a 6-layer printed circuit board with copper surfaces 1 through 6 and with the insulated material 202a between the copper surfaces. The layers of the flex area 201 a extend throughout the total width of the board, as shown. The spacing of the copper surfaces from each other is adjusted for the proper impedance of the printed wires on each layer.

Although the board is first fabricated with the flex material disposed on top of a rigid board material, this rigid board material is removed in the strategic area where the flex area 201 a is formed as a further step in the fabrication process. On the FRONT FACE of the board that affords the flex area, the comb tabs 200a are formed. The width of the flex area is determined by the required length to wrap around the rigid substrate, the required length of the tabs, the connector cavity depth and the clearance required above the body of the connector.

Now referring to FIG. 2b, the comb tabs are shown to be formed on the back side of the flex area. All other aspects of FIG. 2b are the same as in FIG. 2a. Referring next to FIG. 2c, the flex area is fabricated as layers 3 and 4, which are shown to be embedded internal to adjacent layers 2 and 5.

The position of the flex layer is not restricted to any particular layer and can be in any place within the sandwich of layers. The comb tabs 200c are also shown to be on one of the surfaces of the flex area. The other area of the flex can be used for the tabs as well.

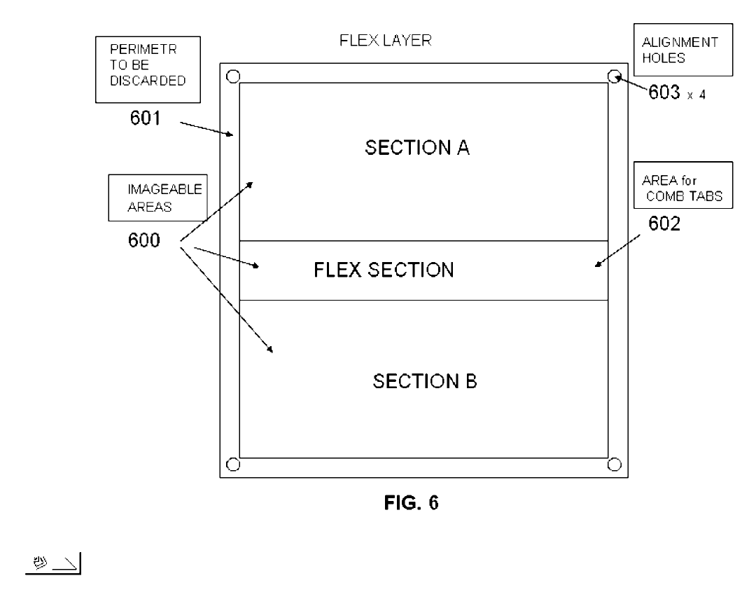

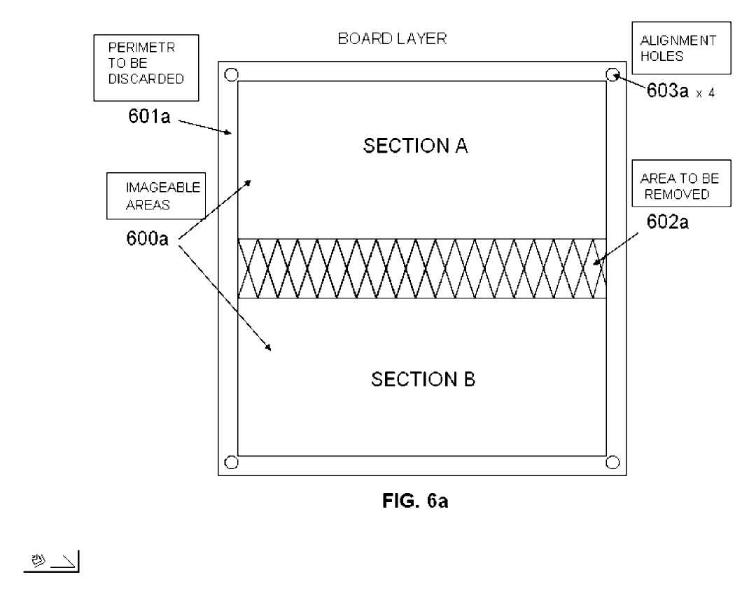

Referring next to FIGS. 6 and 6a the construction of the boards may be better understood. Referring first to FIG. 6, a sample board area that is partitioned in sections is shown. Section A and section B 600 are the circuit board sections to be imaged. The flex section 602 is the section where the comb tabs are imaged and formed. The perimeter 601 facilitates the board construction and will be finally routed out and discarded. There are alignment holes 603 for layer registration and alignment during the imaging, etching and the final sandwiching of all layers.

FIG. 6a shows a sample board area that is partitioned in sections. Section A and section B will be the circuit board sections to be imaged. The cross-hatched section 602a will be the section to be punched out and discarded for all layers, other than the flex layers, before the layers are sandwiched together. The perimeter 601a and alignment holes 603a are the same as in FIG. 6.

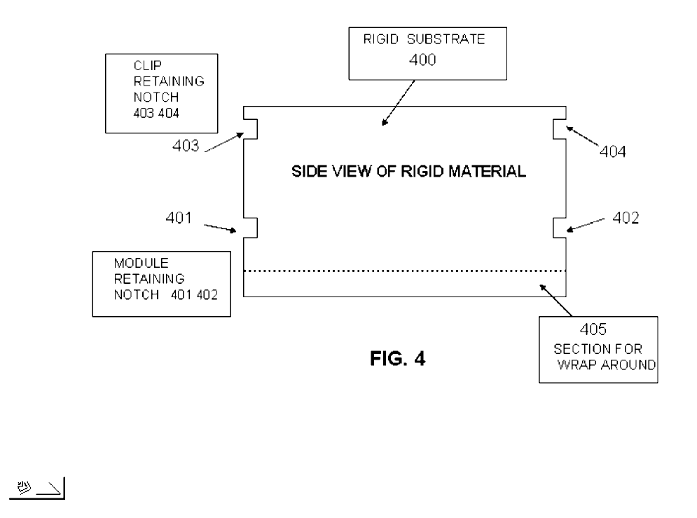

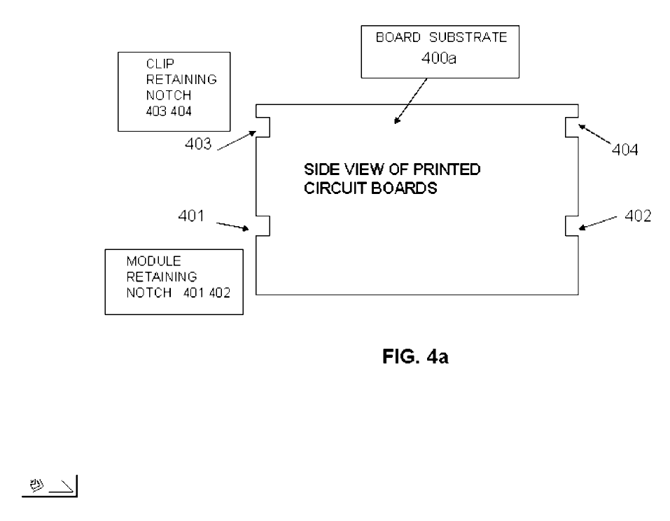

In the process of routing out the perimeter of the boards, the notches 401, 402, 403 and 404 shown in FIGS. 4 and 4a are also formed per design specification for size and location. The imaged layers, as shown in FIGS. 2 and 2a, will be sandwiched together in one of these shown arrangements. The completed boards then go through a component re-flow process and the final assembly constructed by one of the methods depicted in FIGS. 3 and 3a.

Referring now to FIG. 3, the designated rigid substrate 302 is placed with the appropriate edge in area 313 between the comb tabs 311 and 312. Then the boards 300 and 301 are rotated around the rigid substrate so that components 304 and 305 achieve a predetermined distance from 302. Next, the pins 307 and 308 are affixed to achieve a rigid assembly. The flex sections 309 and 310 are allowed to achieve free form to allow the boards to align with the rigid substrate 302, thus achieving parallelism of the boards as shown.

Referring next to FIG. 3a, a variation of the process of FIG. 3 is shown. Components 304 and 305 are allowed to touch the rigid substrate. To maintain this configuration a clip 314 is used. The pressure on the selected outside components of the boards generated by the pressure plates of the clip forces components 304 and 305 to press against the rigid substrate 302. The end retaining tabs 503 on both ends of the clip shown in FIG. 5 will latch in the notches 404 shown in FIG. 4 and FIG. 4a. The notches of the rigid substrate and of the circuit boards will keep the assembly together and in alignment.

Referring now to FIG. 5, the retaining clip assembly 500 is shown. The clip is of metallic material that has springy properties. It is formed in letter “U” shape with pressure plates 501 formed and bent inward to supply spring action. The plate is further indented to form a contact area 502 to force good mechanical contact with the component of the board. The end sides next to the plates are also formed similarly to become pressure plates for the end components. On the upper surface of the clip and at the end of each side an edge retainer 503 is formed to engage into the upper notches 403 and 404 as shown in FIGS. 4 and 4a. The flat upper surface of the clip can be constructed with holes 504 to serve as air vents to allow heat to escape. Instead of holes, rectangular cut-outs or any other shape of vents can be employed.

While the invention has been described with reference to specific embodiments, it will be apparent that improvements and modifications may be made within the purview of the invention without departing from the scope of the invention defined in the appended claims.

1-11. (canceled)

12. A memory expansion board comprising:
(a) a rigid substrate having two opposing lateral sides and an edge;
(b) a flex circuit wrapped about the edge of the rigid substrate, the flex circuit having a first side and a second side, a portion of the flex circuit attached to at least one of the lateral sides of the rigid substrate, the flex circuit having plural contacts adapted for connection to a circuit board socket, the plural contacts being disposed near the edge of the rigid substrate on the outside side of the flex circuit;
(c) plural memory CSPs (ChipScaled Packaged devices) mounted on the first side and second side of the flex circuit.

13. The memory expansion board of claim 12 in which the plural CSPs each have a top surface and one or more of the top surfaces of the plural CSPs is attached to the rigid substrate.

14. The memory expansion board of claim 12 in which the rigid substrate is made of a conductive material.

15. The memory expansion board of claim 12 in which the rigid substrate is made of a thermally conductive material.

16. The memory expansion board of claim 12 in which the rigid substrate has an extension.

17. The memory expansion board of claim 12 further comprising at least one alignment opening of the flex circuit matching at least one alignment opening of the rigid substrate.

18. The memory expansion board of claim 12 further comprising at least one alignment tab of the rigid substrate.

19. A circuit module comprising:
a substrate having a first and second lateral side and a first perimeter edge and a second perimeter edge;
a flex circuit having a first side and a second side, the first side having expansion board contacts adapted for connection to an expansion board slot and having a set of contact arrays, the flex circuit being wrapped about the first perimeter edge of the substrate to place the expansion board contacts of the first side closer to the first perimeter edge of the substrate than is disposed the set of contact arrays and to place the second side of the flex circuit closer to the lateral sides of the substrate than is disposed the first side of the flex circuit.

20. A circuit module comprising:
a substrate having a first and second lateral side and a first perimeter edge and a second perimeter edge;
a flex circuit having a first side and a second side, the first side having expansion board contacts adapted for connection to an expansion board slot and having a set of contact arrays, the flex circuit being wrapped about the first perimeter edge of the substrate to place the expansion board contacts of the first side closer to the second perimeter edge of the substrate than is disposed the set of contact arrays and to place the second side of the flex circuit closer to the lateral sides of the substrate than is disposed the first side of the flex circuit.

21. A circuit module comprising a flex circuit having a first side having contacts adapted for connection to a socket, a second side, and being imposed with a bend to form an open-ended pocket having an inward side and an outward side and being open at one end and closed at the other end of the pocket, the first side of the flex circuit being on the outward side of the pocket and the second side of the flex circuit being on the inward side of the pocket.

22. The circuit module of claim 21 further comprising a rigid interposer disposed at least partially in the open-ended pocket of the flex circuit.

23. The circuit module of claim 22 in which the rigid interposer is made of a conductive material.

24. The circuit module of claim 21 further comprising a support member disposed at least partially in the open-ended pocket of the flex circuit.

25. The circuit module of claim 21 further comprising a heat-conducting member disposed at least partially in the open-ended pocket of the flex circuit.

26. The circuit module of claim 22, in which the rigid interposer has a necked narrow portion disposed adjacent to the closed end of the pocket.

27. The circuit module of claim 21 in which the flex circuit has two end portions, each end portion having a plurality of memory CSPs mounted on the first and second sides of the flex circuit.

28. A method for devising a circuit module comprising the steps of:
providing a flex circuit having first and second sides and first and second long perimeter edges and first and second short perimeter edges with a set of module contacts along the first side and first and second pluralities of CSPs disposed laterally about the set of module contacts to place the first plurality of CSPs nearer the first long perimeter edge of the flex circuit than is disposed the set of module contacts and the second plurality of CSPs nearer the second long perimeter edge of the flex circuit than is disposed the set of module contacts;
a substrate having first and second lateral sides and a first long perimeter edge and a second long perimeter edge;
wrapping the flex circuit about the substrate to dispose the second side of the flex circuit closer to the first and second lateral sides of the substrate than is disposed the first side of the flex circuit and to dispose the set of module contacts nearer the first long perimeter edge of the substrate than the second long perimeter edge of the substrate and to place the first plurality of CSPs closer to the first lateral side of the substrate than is disposed the second plurality of CSPs.

29. The method of claim 28 in which the provided flex circuit has third and fourth pluralities of CSPs.

30. The method of claim 28 in which the CSPs are each stacked modules composed of two or more individual CSPs.

31. A method for providing increased memory capacity for a computer system comprising the steps of:
providing a circuit module devised in accordance with claim 28 and inserting said module into an expansion slot on a motherboard.

32. A method of assembling a circuit module comprising the steps of:
providing a flex circuit having a first side and a second side, the first side having a plurality of pads for mounting components and a plurality of contacts for insertion in an expansion board slot; the second side having a plurality of pads for mounting components;
mounting plural CSPs along the first side of the flex circuit;
mounting plural discrete components along the first side of the flex circuit;
mounting plural CSPs along the second side of the flex circuit;
mounting plural discrete components along the second side of the flex circuit;
providing a rigid substrate having a first and second major surfaces and an edge; and
wrapping the flex circuit about the edge of the rigid substrate, with the first side facing outward, such that a first set of the plurality of contacts are disposed proximal to the edge of the rigid substrate.

33. The method of claim 32 in which the step of wrapping the flex circuit further includes wrapping such that the second set of the plurality of contacts are disposed proximal to the edge of the rigid substrate.

34. The method of claim 32 further including the step of attaching at least one of the plural CSPs along the second side of the flex circuit to the rigid substrate.

35. The method of claim 32 further including the step of thermally connecting at least one of the plural CSPs along the second side of the flex circuit to the rigid substrate.

36. The method of claim 32 further including the step of attaching a heat radiating clip to selected ones of the plural CSPs.

37. The method of claim 32 further including the step of attaching a heat radiating element to at least one of the CSPs along the first side of the flex circuit.

38. The method of claim 32 further including the step of inserting the plurality of contacts at least partially into an expansion board slot for connection to an operating environment.

39. A method of assembling a circuit module comprising the steps of:
providing a flex circuit having a first side and a second side and a plurality of contacts along the first side for insertion in an expansion board slot;
mounting at least first and second CSPs along the first side of the flex circuit;
providing a rigid substrate having a first and second major sides and an edge;
wrapping the flex circuit about the rigid substrate to dispose the first of the at least first and second CSPs closer to the first major side of the rigid substrate than the second major side of the substrate and dispose the second of the at least first and second CSPs closer to the second major side of the rigid substrate than the first major side of the substrate and attaching the flex circuit to the rigid substrate such that the plural contacts are presented proximal to the edge of the rigid substrate for insertion into the expansion board slot.

40. The method of claim 39 in which the steps of attaching the flex circuit to the substrate comprises lamination.

41. The method of claim 39 further comprising mounting third and fourth CSPs along the second side of the flex circuit.

42. The method of claim 39 in which the rigid substrate is made of heat conducting material.

43. The method of claim 39 in which the rigid substrate has a first and second portion, the first portion being thinner than the second portion

44. The method of claim 39 further including the step of thinning the rigid substrate along the edge of the rigid substrate.

45. The method of claim 39 further including the step of aligning a tooling hole of the flex circuit with a tooling hole of the rigid substrate.

46. A populated flexible circuit comprising:
a flexible circuit having a first major side and a second major side, the flexible circuit exhibiting along the first major side, first-side first and second sets of contact site arrays between which is located a row of connector contacts, the second major side of the flexible circuit exhibiting second-side first and second sets of contact site arrays which correspond to the first-side first and second sets of contact site arrays, each of the first-side and second-side first and second sets of contact site arrays comprising at least two surface mounted arrays, the flexible circuit providing connections between the at least two surface mount arrays of each of the first-side first and second sets of contact site arrays and the at least two surface mount arrays of each of the second-side first and second sets contact site arrays;
a plurality of CSPs that populate the at least two surface mount arrays of each of the first-side first and second sets of contact site arrays and the at least two surface mount arrays of each of the second-side first and second sets of contact site arrays.

47. A circuit module comprising:
a rigid substrate having two opposing lateral sides and two opposing end edges;
a flexible circuit wrapped about at least one of the two opposing end edges, the flexible circuit having a first side and a second side each having one or more rows of contact site arrays, a portion of the flex circuit being attached to at least one of the lateral sides of the circuit board, the flex circuit having plural contacts adapted for electrical connection to a card edge connector.

48. The circuit module of claim 47 in which the plural contacts are on the first side of the flex circuit, and in which a portion of the second side of the flex circuit opposite at least some of the plural contacts is laminated to the rigid substrate.

49. A circuit module comprising:
a circuit board having two opposing lateral sides and an edge;
a flexible circuit wrapped around the edge of the rigid substrate, the flex circuit having an inner side and an outer side, the inner and outer sides each having two or more rows of contact site arrays, a portion of the flex circuit being laminated to at least one of the lateral sides of the circuit board, the flex circuit having plural contacts adapted for electrical connection to the circuit board;
a plurality of CSPs mounted to the two or more rows of contacts site arrays of the inner side and the outer side of the flex circuit.

50. A method to encourage the extraction of thermal energy from a CSP that operates in conjunction with at least one other CSP comprising the steps of:
providing a first CSP having a top surface and a bottom surface, there being CSP contacts along the bottom of the surface;
providing a thermally conductive substrate member and attaching the first CSP to the thermally conductive substrate member;
providing a flex circuit and attaching the first CSP to the flex circuit, the attachment being effectuated employing the CSP contacts of the first CSP and employing the thermally conductive substrate member as a support for a part of the flex circuit;
providing a second CSP having a bottom surface and CSP contacts attaching the second CSP to the flex circuit, the attachment being effectuated employing the CSP contacts of the second CSP so that the CSP contacts of the first CSP are separated from the CSP contacts of the second CSP by a part of the flex circuit.

51. The method of claim 50 further comprising a set of contacts electrically connected to the flex circuit to provide connective facility for the first and second CSPs to an operating environment.

52. The method of claim 50 in which the thermally conductive substrate member is comprised of metal.

53. The method of claim 52 in which the thermally conductive substrate member is comprised of aluminum.

54. The method of claim 52 in which the thermally conductive substrate member is comprised of a radiative portion having fins.

55. The method of claim 50 in which the thermally conductive substrate member is comprised of FR4 and a metallic layer.

56. The method of claim 50 in which the attachment of the first CSP to the thermally conductive substrate member is by the top surface of the first CSP.

57. A circuit module to encourage the extraction of thermal energy from a CSP that operates in conjunction with at least one other CSP comprising:
a first CSP having a top surface and a bottom surface and CSP contact, the CSP contacts being along the bottom surface;
a thermally conductive substrate member attached to the first CSP;
a flex circuit attached to the first CSP, the attachment being effectuated employing the CSP contacts of the first CSP, the thermally conductive substrate member being a support for a part of the flex circuit;
a second CSP attached the flex circuit, the attachment being effectuated employing the CSP contacts of the second CSP so that the CSP contacts of the first CSP are separated from the CSP contacts of the second CSP by at least a part of the flex circuit.
